(19) United States
(12) Patent Application Publication
(10) Pub. No.: US 2026/0033304 A1
(43) Pub. Date: Jan. 29, 2026

(54) SUBSTRATE PROCESSING METHOD

(71) Applicants: SCREEN Holdings Co., Ltd., Kyoto (JP); IMEC VZW, Leuven (BE)

(72) Inventors: Teppei NAKANO, Ismaning (DE); Quoc Toan LE, Leuven (BE)

(21) Appl. No.: 19/099,743

(22) PCT Filed: Sep. 12, 2023
(86) PCT No.: PCT/JP2023/033119

§ 371 Date: Jan. 29, 2025

(30) Foreign Application Priority Data
Jul. 29, 2022 (JP) 2022-122078

(51) Int. Cl. H01L 21/768; H01L 21/3213

(52) U.S. Cl. CPC H01L 21/76885; H01L 21/32138

(57) ABSTRACT

A substrate processing method processes a substrate having a metal layer and a hard mask that is laminated on the metal layer on a surface. This method includes a step of dry etching and patterning the metal layer exposed from the hard mask, a step of irradiating an ultraviolet ray to a residue generated on the surface of the substrate by the dry etching, and a step of removing the residue from the substrate by wet processing in which a residue removing liquid having a pH (hydrogen ion exponent) of not less than 7 and not more than 14 is supplied to the surface of the substrate after irradiation of the ultraviolet ray. The residue contains one or more types of metal oxide, metallic halide, and an organic metallic substance each of which contains an element of a main constituent metal of the metal layer.

### TECHNICAL FIELD

The present invention relates to a substrate processing method. A substrate to be processed includes a semiconductor wafer, a substrate for a flat panel display (FPD) such as a liquid crystal display device and an organic electroluminescence (EL) display device, a ceramic substrate, and a substrate for a solar cell. The method of the present invention is particularly suitable for substrate processing in which dry etching is performed on a metal layer formed on a surface.

### BACKGROUND ART

A process of forming a multilayer wiring layer on a semiconductor substrate after forming an active device, etc., on the semiconductor substrate is called a back end of line (BEOL: wiring process). The multilayer wiring layer includes an interlayer insulating film, a metal wiring layer, and a via formed in the interlayer insulating film. The via is formed by forming a through hole (via opening) in the interlayer insulating film and embedding a metal (via metal) in the through hole. A portion between different wiring layers is connected to each other through the via.

The process of forming the multilayer wiring layer is described in Patent Literature 1, for example. In Patent Literature 1, aluminum, ruthenium, cobalt, a cobalt-aluminum alloy, tungsten, molybdenum, nickel, rhodium, iridium, zinc, and copper are included as a material of a conductive film that forms wiring.

### CITATION LIST

### Patent Literature

Patent Literature 1: Japanese Patent Application Publication No. 2021-19006

### SUMMARY OF INVENTION

### Technical Problem

Ruthenium and molybdenum have attracted attention as a metal material that constitutes the multilayer wiring layer in the structures of recent miniaturized semiconductor devices. For example, as a technique of forming multilayer wiring in which ruthenium is used, a semi-Damascene process has been proposed. The semi-Damascene process is a technique of forming a via opening in an interlayer insulating film and then forming a via metal that fills the via opening and a wiring film of an upper layer collectively. After the film formation, the wiring film is patterned into wiring patterns by direct metal etching. By using a metal material to which the direct metal etching can be performed, it is possible to apply the semi-Damascene process.

The direct metal etching is a process to form a hard mask on the wiring film and to remove an unnecessary portion of the wiring film by dry etching through the hard mask. Since residue due to the dry etching is generated on a surface of the semiconductor substrate after the dry etching, there is a need to perform a cleaning process to remove the residue (residue removal processing). This cleaning process requires a cleaning performance that minimizes damage to the hard mask and the wiring as much as possible and removes the residue as efficiently as possible. The damage to the wiring, that is, film reduction leads to an increase in wiring resistance. Also, the residue that remains between the wirings increases the risk of leakage between the wirings. Therefore, both affect the electrical characteristics of a final product.

Thus, a preferred embodiment of the present invention provides a substrate processing method to efficiently remove a residue after dry etching of a metal layer while suppressing damage to the metal layer.

### Solution to Problem

A preferred embodiment of the present invention provides a substrate processing method that has the following characteristics.

1. A substrate processing method that processes a substrate having, on a surface thereof, a metal layer and a hard mask that is laminated on the metal layer, including:
a step of dry etching and patterning the metal layer exposed from the hard mask,
a step of irradiating an ultraviolet ray to a residue generated on the surface of the substrate by the dry etching, the residue containing one or more types of metal oxide, metallic halide, and an organic metallic substance each of which contains an element of a main constituent metal of the metal layer, and
a step of removing the residue from the substrate by wet processing in which a residue removing liquid having a pH (hydrogen ion exponent) of not less than 7 and not more than 14 (more preferably, not less than 8 and not more than 14, and further preferably, not less than 10 and not more than 14) is supplied to the surface of the substrate after irradiation of the ultraviolet ray.

According to this method, the metal layer is dry etched through the hard mask, and thereby, it is possible to pattern the hard mask. Therefore, the main constituent metal of the metal layer is a metal material to which patterning by the dry etching can be applied. The main constituent metal indicates a metal material other than a minute amount of additives, etc., that can be contained in the metal layer.

The dry etching is a plasma process in which the etching progresses as the active species of a processing gas attacks the exposed portion of the metal layer. After the dry etching, the residue (dry etching residue) containing a compound of the element of the main constituent metal of the metal layer and a compound with a constituent element of the processing gas (metal compound) remains on the substrate. Specifically, the compound that constitutes the residue contains at least one or more types of the metal oxide, the metallic halide, and the organic metallic substance.

The ultraviolet ray is irradiated toward the residue as described above. The ultraviolet ray is a preprocessing for breaking a chemical bond of the compound contained in the residue, modifying the residue, and facilitating removal of the residue by wet processing after that. By performing wet processing in which a residue removing liquid is supplied after this preprocessing, the residue is removed outside from the surface of the substrate. By using a processing liquid having a pH of not less than 7 and not more than 14 (more preferably, not less than 8 and not more than 14, and further preferably, not less than 10 and not more than 14) as the residue removing liquid, it is possible to efficiently remove the residue.

According to an experiment by the present inventors, although the residue could not be efficiently removed with an acid-based processing liquid (acid processing liquid), the residue could be efficiently removed with an alkaline-based processing liquid (neutral or alkaline processing liquid, more preferably, an alkaline processing liquid). Also, the acid processing liquid corrodes an oxide film, etc., on the substrate and damages the structure on the substrate. Thus, also from this point of view, it is proper to use the alkaline-based processing liquid as the residue removing liquid.

The irradiation of the ultraviolet ray performed before supply of the residue removing liquid is a non-contact process, and while it affects the residue, it does not substantially cause physical damage to other structures on the substrate (such as the metal layer and an insulating layer). Therefore, unlike plasma processing, etc., it is possible to selectively act on the chemical bond of the residue. Thus, characteristics of a final product manufactured through substrate processing are less affected.

2. A substrate processing method for processing a substrate in which a hard mask and a metal layer patterned by dry etching through the hard mask are formed on a surface of the substrate, and in which a residue by the dry etching, the residue containing one or more types of metal oxide, metallic halide, and an organic metallic substance each of which contains an element of a main constituent metal of the metal layer is generated on the surface of the substrate, the substrate processing method including:
a step of irradiating an ultraviolet ray to the residue, and
a step of removing the residue from the substrate by wet processing in which a residue removing liquid having a pH (hydrogen ion exponent) of not less than 7 and not more than 14 (more preferably, not less than 8 and not more than 14, and further preferably, not less than 10 and not more than 14) is supplied to the surface of the substrate after irradiation of the ultraviolet ray.

In the method of the present preferred embodiment, the substrate after patterning the metal layer by the dry etching is an object to be processed. Also, in the method of the present preferred embodiment, the same operations and effects as the method described above are exerted.

3. The substrate processing method described in the clause 1. or 2., wherein the metal layer contains, as the main constituent metal, at least one type selected from a metal material group consisting of molybdenum, ruthenium, and aluminum, and a metal compound containing these metals.

For example, it is possible to apply the substrate processing method of the present preferred embodiment to a wiring formation step of forming a wiring layer (typically, a multilayer wiring layer) on a substrate. Specifically, by forming the metal layer with a wiring metal material, forming the hard mask corresponding to the wiring patterns on the metal layer, and performing the dry etching, it is possible to pattern the metal layer into the wiring patterns.

For example, a material that constitutes minute wiring of a semiconductor device is selected in consideration to resistivity, diffusivity to the other material layers, etc. In the semi-Damascene technique that is one of the wiring formation techniques to be applied when multilayer wiring is formed on a semiconductor substrate, having acceptable resistivity as a wiring film, being capable of depositing without a diffusion barrier, and being capable of patterning by the dry etching (direct metal etching) are conditions at the time of selecting the wiring metal material. A metal that satisfies such conditions can be exemplified by molybdenum, ruthenium, and aluminum, as well as a molybdenum-based, a ruthenium-based, or an aluminum-based metal compound.

By applying the substrate processing method of the present preferred embodiment, it is possible to reduce the risk of leakage between the wirings due to the residue, and it is also possible to reduce the risk of an increase in specific resistance due to film reduction of the wirings at the time of residue removal processing.

4. The substrate processing method described in any one of the clauses 1. to 3., further including an atmosphere control step of controlling an atmosphere in a periphery of the substrate during the irradiation of the ultraviolet ray to a low oxygen atmosphere of a lower oxygen concentration than an oxygen concentration in an air atmosphere.

When the ultraviolet ray is radiated in an atmosphere of a high oxygen concentration, ozone is generated, and there is a possibility that oxidation of the metal layer may be caused by the ozone. Metal oxide is formed on a surface of the metal layer, and when the metal oxide is etched with the residue removing liquid, film reduction of the metal layer is caused. Thus, by performing the irradiation of the ultraviolet ray in a low oxygen atmosphere, it is possible to reduce the risk of film reduction of the metal layer.

5. The substrate processing method described in the clause 4., wherein the atmosphere control step includes an inert gas supply step of supplying an inert gas to the periphery of the substrate.

6. The substrate processing method described in any one of the clauses 1. to 5., wherein the ultraviolet ray has energy that is not less than bond energy of at least one compound of the metal oxide, the metallic halide, and the organic metallic substance contained in the residue.

By this method, by the irradiation of the ultraviolet ray, it is possible to break a chemical bond of at least one of the metal oxide, the metallic halide, and the organic metallic substance in the residue and modify the residue. Thereby, it is possible to efficiently perform removal of the residue with the residue removing liquid.

The residue that remains on the surface of the substrate after the dry etching typically contains a metal compound in which the main constituent metal of the metal layer to be etched, and the constituent element of the processing gas for the dry etching are bonded. Since the ultraviolet ray has a wavelength capable of being absorbed into the residue and has energy that is not less than bond energy of the main constituent metal and the constituent element of the processing gas, it is possible to modify the residue into a substance that is easily removed with the residue removing liquid.

For example, in a case where the main constituent metal is molybdenum, and the residue contains a compound in which molybdenum and one or more elements of carbon, chlorine, oxygen, and fluorine are bonded, it is preferable that the ultraviolet ray has energy of not less than 465 kJ/mol (preferably, not less than 596 kJ/mol). Since the molybdenum compound is capable of absorbing the energy of the ultraviolet ray, by the irradiation of the ultraviolet ray, it is possible to break at least part of the bond of the molybdenum compound. Thus, it is possible to modify the residue.

7. The substrate processing method described in any one of the clauses 1. to 6., wherein the ultraviolet ray increases a hydrophilic property of a surface of the metal layer.

By this method, the hydrophilic property on the surface of the metal layer is increased. Thus, the residue removing liquid more easily infiltrates. Therefore, even when the metal layer is patterned into a minute structure, by infiltration of the residue removing liquid into the minute structure, it is possible to efficiently remove the residue.

8. The substrate processing method described in any one of the clauses 1. to 7., wherein the main constituent metal is molybdenum, and a wavelength of the ultraviolet ray is not more than 257 nm (more preferably, not more than 201 nm).

By the irradiation of the ultraviolet ray of a wavelength range of not more than 257 nm, it is possible to give energy required for breaking the chemical bond in which molybdenum and at least one element among carbon, chlorine, oxygen, and fluorine are bonded, and it is possible to effectively modify the residue. More preferably, by the irradiation of the ultraviolet ray of a wavelength range of not more than 201 nm, it is possible to substantially break the chemical bond of the molybdenum compound in which molybdenum and carbon, chlorine, oxygen, and fluorine are bonded. Thus, it is possible to furthermore effectively modify the residue.

9. The substrate processing method described in any one of the clauses 1. to 8., wherein the residue removing liquid does not contain an oxidant but contains one or more selected from ammonium hydroxide, a tetramethylammonium hydroxide aqueous solution (TMAH), and a polymer removing liquid.

The polymer removing liquid is a chemical liquid for removing a residue of a photoresist after a plasma process. As the polymer removing liquid, a liquid that contains an organic alkaline liquid, a liquid that contains organic acid, a liquid that contains inorganic acid, and a liquid that contains an ammonium fluoride-based substance, etc., are known. However, among these, a liquid having a pH of not less than 7 and not more than 14 (more preferably, not less than 8 and not more than 14, and further preferably, not less than 10 and not more than 14) can be used. Specifically, the liquid that contains the organic alkaline liquid can be used as the residue removing liquid. The liquid that contains the organic alkaline liquid includes a liquid that contains at least any one of dimethylformamide (DMF), dimethylsulfoxide (DMSO), hydroxylamine, and choline. Additionally, the polymer removing liquid that can be used as the residue removing liquid includes a liquid that contains at least any one of 1-methyl-2-pyrrolidone, tetrahydrothiophene 1,1-dioxide, isopropanolamine, monoethanolamine, 2-(2-aminoethoxy) ethanol, catechol, N-methylpyrrolidone, aromatic diol, perclene (tetrachloroethylene), and a liquid that contains phenol, etc., and more specifically includes at least any one of a mixed liquid of 1-methyl-2-pyrrolidone, tetrahydrothiophene 1,1-dioxide, and isopropanolamine, a mixed liquid of dimethylsulfoxide and monoethanolamine, a mixed liquid of 2-(2-aminoethoxy) ethanol, hydroxylamine, and catechol, a mixed liquid of 2-(2-aminoethoxy) ethanol and N-methylpyrrolidone, a mixed liquid of monoethanolamine, water, and aromatic diol, and a mixed liquid of perclene (tetrachloroethylene) and phenol, etc. Additionally, the polymer removing liquid includes a liquid that contains at least any one of amines such as triethanolamine and pentamethyldiethylenetriamine, propylene glycol, and dipropylene glycol monomethyl ether, etc.

10. The substrate processing method described in any one of the clauses 1. to 9., wherein the hard mask is made of an inorganic substance.

For example, the hard mask may be made of a silicon nitride film.

### BRIEF DESCRIPTION OF DRAWINGS

FIGS. 1A to 1D are graphically-illustrated cross-sectional views showing in order some of a manufacturing process of a semiconductor device to which a substrate processing method according to a preferred embodiment of the present invention can be applied.

FIG. 2 is a cross-sectional view taken along line II-II in FIG. 1A, showing a structure of a cut surface.

FIGS. 3A, 3B, and 3C are graphically-illustrated cross-sectional views for describing the substrate processing method according to the preferred embodiment of the present invention.

FIG. 4 is a microphotograph of a sample in a state where dry etching of a molybdenum layer is performed through a hard mask.

FIGS. 5A, 5B, and 5C are microphotographs showing states where, without performing irradiation of an ultraviolet ray to an object surface to be processed of the sample, a processing liquid is supplied and residue removal processing is performed.

FIGS. 6A, 6B, and 6C are microphotographs showing states where, after the irradiation of the ultraviolet ray to the object surface to be processed of the sample, the processing liquid is supplied and the residue removal processing is performed.

FIG. 7 is a view for describing another effect by the irradiation of the ultraviolet ray, showing an effect of an increase in a hydrophilic property by the irradiation of the ultraviolet ray.

### DESCRIPTION OF EMBODIMENTS

Hereinafter, a preferred embodiment of the present invention will be described in detail with reference to the attached drawings.

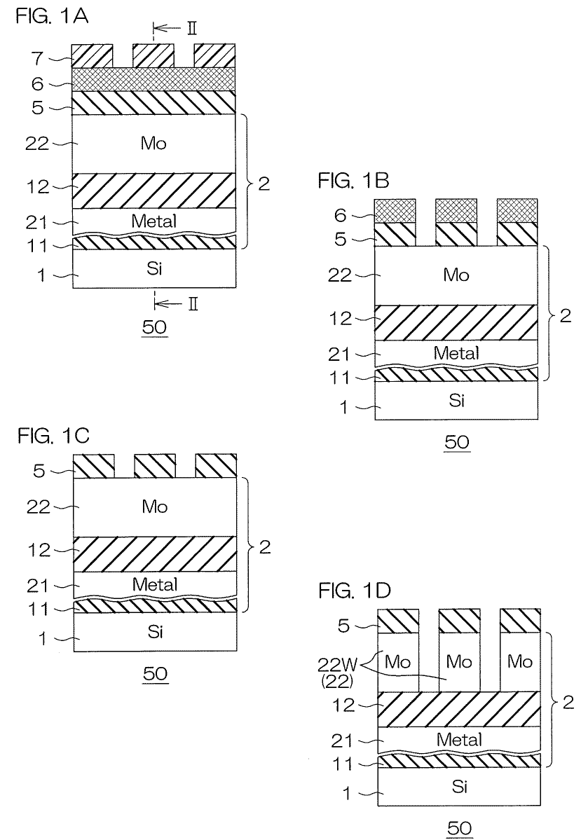

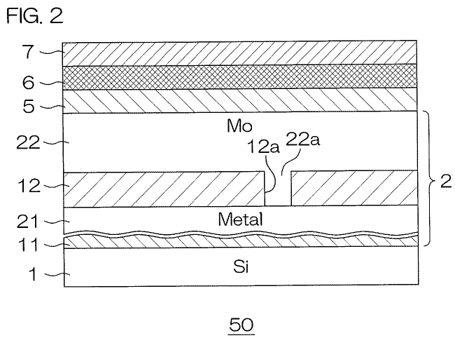

FIGS. 1A to 1D are graphically-illustrated cross-sectional views showing in order some of a manufacturing process of a semiconductor device to which a substrate processing method according to a preferred embodiment of the present invention can be applied. Also, FIG. 2 is a cross-sectional view taken along line II-II in FIG. 1A, showing a structure of a cut surface. Here, part of a back end of line (BEOL: wiring step) that forms a multilayer wiring layer 2 on a surface of a silicon substrate 1 serves as an example of a semiconductor substrate. Also, here, an example in which a single metal wiring layer that constitutes the multilayer wiring layer 2 is formed by a semi-Damascene step will be described. In the following description, a “substrate 50” means an entire structure including the silicon substrate 1 and various films formed in the surface (such as an insulating film, a metal film, and a resist film).

First, FIGS. 1A and 2 will be referred to. A device (an active device and/or a passive device) such as a transistor is formed in a surface layer portion of the silicon substrate 1, and the multilayer wiring layer 2 is formed in a principal surface on the side where the device is formed.

The multilayer wiring layer 2 includes interlayer insulating films 11, 12, and a plurality of metal wiring layers 21, 22. The interlayer insulating films 11, 12 are typically made of silicon oxide. The metal wiring layer 21 (metal wiring layer of the lower layer) is formed above the interlayer insulating film 11. This metal wiring layer 21 may be made of, for example, copper, ruthenium, molybdenum, etc. Although details are not shown in the figure, the metal wiring layer 21 is typically patterned into desired wiring patterns. The other interlayer insulating film 12 is formed on the metal wiring layer 21. The other metal wiring layer 22 (metal wiring layer of the upper layer) is formed on this interlayer insulating film 12. In the present preferred embodiment, this metal wiring layer 22 is formed by the semi-Damascene step.

A specific description will be given. A via opening 12a that passes through the interlayer insulating film 12 in the film thickness direction and exposes the metal wiring layer 21 of the lower layer is formed in the interlayer insulating film 12. The metal wiring layer 22 of the upper layer is formed on the interlayer insulating film 12. At a stage of FIG. 1A, this metal wiring layer 22 covers an entire surface of the interlayer insulating film 12, and has a via metal portion 22a embedded in the via opening 12a (see FIG. 2). A main constituent metal of the metal wiring layer 22 is molybdenum that serves as an example here. For example, by a plasma chemical vapor deposition (CVD) method, it is possible to form the metal wiring layer 22 of molybdenum.

On the metal wiring layer 22, a hard mask 5 that covers an entire surface thereof (film before patterning) is laminated. The hard mask 5 is typically made of an inorganic insulating material, and for example, made of silicon nitride that serves as an example of the inorganic insulating material. On the hard mask 5, an amorphous carbon layer 6 that covers an entire surface thereof (in a state before patterning) is formed. On the surface of the amorphous carbon layer 6, a photoresist mask 7 for patterning the metal wiring layer 22 into the desired wiring patterns is formed. This photoresist mask 7 is in an already-patterned state after a photo-exposing step and a development step. The photoresist mask 7 and the amorphous carbon layer 6 constitute a multilayer resist for patterning the hard mask 5.

Next, as shown in FIG. 1B, by dry etching with the photoresist mask 7 as a mask, the amorphous carbon layer 6 is etched. Thereby, patterns of the photoresist mask 7 are transferred to the amorphous carbon layer 6, and the surface of the hard mask 5 is selectively exposed from an opening (through hole) formed in the amorphous carbon layer 6. When the dry etching is further continued, by dry etching with the amorphous carbon layer 6 as a mask, the hard mask 5 is etched. Thereby, patterns of the amorphous carbon layer 6 are transferred to the hard mask 5, and the metal wiring layer 22 is selectively exposed from an opening (through hole) formed in the hard mask 5. After this etching, cleaning process is executed to remove the residue of the photoresist mask 7 after the dry etching. This state is shown in FIG. 1B.

Next, as shown in FIG. 1C, etching for removing the amorphous carbon layer 6 (for example, wet etching) is executed, and the cleaning process on the surface of the substrate 50 is further performed.

Then, as shown in FIG. 1D, by dry etching with the hard mask 5 as a mask, the metal wiring layer 22 is etched. Thereby, patterns of the hard mask 5 are transferred to the metal wiring layer 22. Thereby, the metal wiring layer 22 is patterned into the desired wiring patterns. This step is so-called direct metal etching, and here, by direct metal etching to the metal wiring layer 22 that is made of molybdenum, the wiring patterns that are made of molybdenum are formed on the interlayer insulating film 12.

The wiring patterns may have a plurality of linear wirings 22W that extend in the direction of crossing a paper plane of FIG. 1D, for example. Between the adjacent wirings 22W, the surface of the interlayer insulating film 12 is exposed, and a portion between those wirings 22W is insulated. The portion between the adjacent wirings 22W may be an air gap or an insulating material may be embedded in the portion. At least one of the wirings 22W has the via metal portion 22a embedded in the via opening 12a that is formed in the interlayer insulating film 12 (see FIG. 2), and is sterically connected to the metal wiring layer 21 of the lower layer through the via metal portion 22a.

In this example, the semi-Damascene step includes formation of the via opening 12a in the interlayer insulating film 12, formation of the metal wiring layer 22 that embeds the via opening 12a and covers the interlayer insulating film 12, and patterning of the metal wiring layer 22 by the direct metal etching.

The direct metal etching of the metal wiring layer 22 performed through the hard mask 5 is performed by the dry etching, in detail, by reactive ion etching. Such dry etching involves a plasma process of introducing a processing gas for etching into a processing chamber, irradiating an electromagnetic wave such as a microwave to the processing gas, and making the processing gas plasma. Thereby, active species of the processing gas are generated, and by guiding the active species of the processing gas to the metal wiring layer 22, it is possible to perform anisotropic etching that etches the metal wiring layer 22 in the thickness direction thereof.

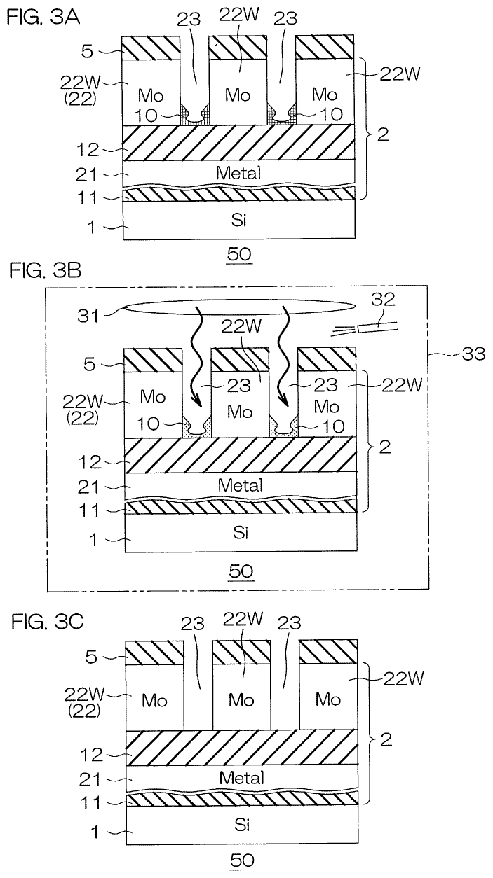

On the surface of the substrate 50 after this dry etching, a compound of a metal material that constitutes the metal wiring layer 22 and a constituent element of the processing gas (metal compound) remains as a residue 10 (see FIG. 3A). In particular, the residue 10 that remains between the wirings 22W, specifically the residue that remains in a side wall or a bottom portion of an opening portion 23 between the wirings 22W can be a cause of leakage between the wirings. Thus, there is a need for residue removal processing.

A condition required for the residue removal processing is being capable of removing the residue 10 and having less effect on the other structures on the substrate 50. In particular, a process that corrades the wirings 22W is not preferable since the processing causes film reduction of the wirings 22W and there is the risk of an increase in specific resistance of the wirings 22W. Also, a process that corrades the hard mask 5 is not preferable as well since the processing increases exposed parts of the wirings 22W, which may result in the possibility of film reduction of the wirings 22W. Further, processing of corrading the interlayer insulating film 12 that is a foundation of the metal wiring layer 22 is not preferable since the processing increases the risk of leakage between the upper and lower metal wiring layers 21, 22 and affects the capacitance a volume between the metal wiring layers 21, 22.

As the processing gas for the dry etching, a fluorine-based gas (of CF₄, CHF₃, SF₆, etc.) or a chlorine-based gas (of CCl₄, BCl₃, etc.) are typically used, and a gas of H₂, O₂, N₂, etc., is mixed with these according to need. Therefore, the residue 10 after the dry etching contains one or more types of metal oxide, metallic halide, and an organic metallic substance of the main constituent metal that constitutes the metal wiring layer 22 serves as an object to be etched. In a case where the main constituent metal is molybdenum, it is highly likely that one or more types of metal compounds of MoOx, MoClx, MoFx, MoCx, etc., (wherein x in a chemical formula of each compound denotes a number that represents a composition ratio with respect to molybdenum, and does not mean equality between the different listed compounds) constitute the residue 10. The main constituent metal means a metal other than a minute amount of additives, etc., here.

The present inventors performed experiments in which the residue 10 was removed from the substrate 50 after the dry etching (in a state of FIG. 1D) by using hydrofluoric acid, ammonium hydroxide, and a tetramethylammonium hydroxide aqueous solution (TMAH). However, even in the experiments in which any of the chemical liquids were used, removal of the residue 10 on the substrate 50 was insufficient as a result. In addition, in the experiment in which hydrofluoric acid was used, film reduction of the wirings 22W, the hard mask 5, and the interlayer insulating film 12 that is the foundation was also observed. Details of these experiments will be described later.

FIGS. 3A, 3B, and 3C are graphically-illustrated cross-sectional views for describing the substrate processing method according to the preferred embodiment of the present invention, and especially show the residue removal processing to the substrate 50 after the dry etching of patterning the metal wiring layer 22.

As shown in FIG. 3A, the residue 10 after the dry etching remains in the surface of the substrate 50 to be processed, and especially there is often a case where the residue 10 is generated in the opening portion 23 between the adjacent wirings 22W. The residue 10 is attached to the side wall of the opening portion 23 (that is, side walls of the wirings 22W) and the bottom portion (that is, the surface of the interlayer insulating film 12), and typically many exist in the vicinity of the bottom portion of the opening portion 23.

Ultraviolet ray irradiation processing is executed on such a substrate 50 to be processed as shown in FIG. 3B. Specifically, an ultraviolet ray is irradiated to the surface of the substrate 50 on the side where the wirings are formed (hereinafter, referred to as the “object surface to be processed”) from an ultraviolet ray irradiation unit. The ultraviolet ray irradiation unit may be an ultraviolet ray lamp unit 31. In this case, it is preferable that the ultraviolet ray lamp unit 31 is brought sufficiently close to the object surface to be processed of the substrate 50 and attenuation of the ultraviolet ray until reaching the residue 10 is reduced. For example, a distance from a light irradiation surface of the ultraviolet ray lamp unit 31 to the object surface to be processed of the substrate 50 may be approximately 2 mm. The ultraviolet ray irradiation unit may be an ultraviolet ray laser unit that scans the object surface to be processed by ultraviolet ray laser.

The ultraviolet ray irradiated to the object surface to be processed of the substrate 50 has energy that is not less than bond energy of the metal compound contained in the residue 10, specifically, at least one compound of the metal oxide, the metallic halide, and the organic metallic substance. In other words, a wavelength of the ultraviolet ray is selected so that the ultraviolet ray has such energy. By irradiating such an ultraviolet ray, it is possible to break a chemical bond of at least part of the metal compound that constitutes the residue 10. Thus, it is possible to modify the residue 10.

For example, in a case where the main constituent metal of the metal wiring layer is molybdenum, and therefore, the residue 10 is molybdenum oxide, molybdenum halide, or an organic molybdenum-based substance, the ultraviolet ray preferably has energy of not less than 465 kJ/mol (preferably, not less than 596 kJ/mol). A corresponding wavelength range is not more than 257 nm (preferably, not more than 201 nm). For example, bond energy of MoO₃ is 596 kJ/mol, bond energy of MOC is 481 kJ/mol, and bond energy of MoF is 465 kJ/mol. By irradiating an ultraviolet ray that has energy of not less than 465 kJ/mol, in other words, an ultraviolet ray of a wavelength of not more than 257 nm to the residue 10, it is possible to break a chemical bond of at least MoF. Thereby, it is possible to modify the residue 10. Also, by irradiating an ultraviolet ray that has energy of not less than 596 kJ/mol, in other words, an ultraviolet ray of a wavelength of not more than 201 nm, it is possible to break a chemical bond of the molybdenum oxide, the organic molybdenum-based substance, and the molybdenum halide. Thus, it is possible to more effectively modify the residue 10. An irradiation time of the ultraviolet ray may be, for example, 30 seconds to 120 seconds.

The irradiation of the ultraviolet ray is a non-contact process that does not contact the substrate 50, and while it can affect and modify the residue 10, it does not substantially cause physical damage to the other structures on the substrate 50 (such as the metal wiring layer 22, the interlayer insulating film 12, and the hard mask 5). Therefore, unlike plasma processing, etc., the irradiation selectively acts on the chemical bond of the residue 10. Thus, characteristics of a final product (here, the semiconductor device) manufactured through substrate processing are less affected.

In the present preferred embodiment, at the time of the irradiation of the ultraviolet ray to the substrate 50, an atmosphere control step of controlling an atmosphere in a periphery of the object surface to be processed of the substrate 50 to a low oxygen atmosphere is executed. The low oxygen atmosphere is an atmosphere of a lower oxygen concentration than an oxygen concentration in the air atmosphere. More specifically, the low oxygen atmosphere is preferably an atmosphere of an oxygen concentration of not more than 100,000 PPM. The atmosphere control step may be an inert gas supply step of supplying an inert gas (such as a nitrogen gas) to the object surface to be processed of the substrate 50. Specifically, an inert gas nozzle 32 that supplies the inert gas to a portion between the ultraviolet ray lamp unit 31 and the object surface to be processed of the substrate 50 may be provided. Also, the ultraviolet ray irradiation processing may be executed in a sealed chamber 33 and the inert gas may be introduced into the sealed chamber 33, so that an interior of the sealed chamber 33 is an inert gas atmosphere.

When the ultraviolet ray is radiated in an atmosphere of a high oxygen concentration, oxygen is ionized, ozone is generated, and there is a possibility that oxidation may be generated on a surface of a metal layer that constitutes the wirings 22W by the ozone. Thereby, when the metal oxide is generated on surfaces of the wirings 22W, it may cause film reduction of the wirings 22W in wet processing to be performed later, and thereby, the risk of an increase in the specific resistance of the wirings 22W is enhanced. Thus, by performing the ultraviolet ray irradiation processing in the low oxygen atmosphere, it is possible to suppress generation of the metal oxide in the surfaces of the wirings 22W and reduce the risk of an increase in the specific resistance.

After the residue 10 is modified by the irradiation of the ultraviolet ray, as shown in FIG. 3C, a residue removal step is executed to remove the residue 10 by wet processing in which the residue removing liquid is supplied to the substrate 50. Supply of the residue removing liquid to the substrate 50 may be performed by discharging the residue removing liquid into the air toward the object to be processed of the substrate 50 from a nozzle, or may be performed by immersion processing in which the substrate 50 is immersed in a processing layer in which the residue removing liquid is stored.

As the residue removing liquid, an alkaline-based chemical liquid (neutral or alkaline chemical liquid, more preferably, an alkaline chemical liquid) having a pH (hydrogen ion exponent) of not less than 7 and not more than 14 (more preferably, not less than 8 and not more than 14, and further preferably, not less than 10 and not more than 14) is preferable. With an acid chemical liquid, there is a possibility that the removal of the residue 10 is insufficient, and in addition, there is a possibility that the film reduction of the wirings 22W, the hard mask 5, and the interlayer insulating film 12, etc., may be caused and characteristics of a final device may be affected.

Also, the residue removing liquid is preferably a processing liquid that does not contain an oxidant (such as ozone and a hydrogen peroxide solution). A processing liquid that contains the oxidant generates oxide in the surfaces of the wirings 22W, and with the oxide being dissolved into the residue removing liquid and being etched, there is a possibility that it may cause film reduction of the wirings 22W.

Therefore, a particularly suitable processing liquid as the residue removing liquid is an alkaline-based chemical liquid that does not contain the oxidant. More specifically, preferably, the residue removing liquid does not contain the oxidant but contains one or more selected from ammonium hydroxide, a tetramethylammonium hydroxide aqueous solution (TMAH), and a polymer removing liquid. The residue removing liquid may be supplied to the substrate 50 at a temperature from a room temperature to approximately 80° C.

The ammonium hydroxide is an ammonium aqueous solution, and diluted ammonium hydroxide is preferably used.

The polymer removing liquid is a chemical liquid for removing a residue of a photoresist after the plasma process, typically, the photoresist after being used as the mask of the dry etching. As the polymer removing liquid, a liquid that contains an organic alkaline liquid, a liquid that contains organic acid, a liquid that contains inorganic acid, and a liquid that contains an ammonium fluoride-based substance, etc., are known. However, among these, a liquid having a pH of not less than 7 and not more than 14 (more preferably, not less than 8 and not more than 14, and further preferably, not less than 10 and not more than 14) can be used. Specifically, the liquid that contains the organic alkaline liquid can be used as the residue removing liquid. The liquid that contains the organic alkaline liquid includes a liquid that contains at least any one of dimethylformamide (DMF), dimethylsulfoxide (DMSO), hydroxylamine, and choline. Additionally, the polymer removing liquid that can be used as the residue removing liquid includes a liquid that contains at least any one of 1-methyl-2-pyrrolidone, tetrahydrothiophene 1,1-dioxide, isopropanolamine, monoethanolamine, 2-(2-aminoethoxy) ethanol, catechol, N-methylpyrrolidone, aromatic diol, perclene (tetrachloroethylene), and a liquid that contains phenol, etc., and more specifically includes at least any one of a mixed liquid of 1-methyl-2-pyrrolidone, tetrahydrothiophene 1,1-dioxide, and isopropanolamine, a mixed liquid of dimethylsulfoxide and monoethanolamine, a mixed liquid of 2-(2-aminoethoxy) ethanol, hydroxylamine, and catechol, a mixed liquid of 2-(2-aminoethoxy) ethanol and N-methylpyrrolidone, a mixed liquid of monoethanolamine, water, and aromatic diol, and a mixed liquid of perclene (tetrachloroethylene) and phenol, etc. Additionally, the polymer removing liquid includes a liquid that contains at least any one of amines such as triethanolamine and pentamethyldiethylenetriamine, propylene glycol, and dipropylene glycol monomethyl ether, etc.

After the residue 10 is removed with the residue removing liquid, a rinse process is performed in which a rinse liquid (such as deionized water) is supplied to the substrate 50 to wash away the chemical liquid, and then a drying process is performed to remove the liquid component from the substrate 50.

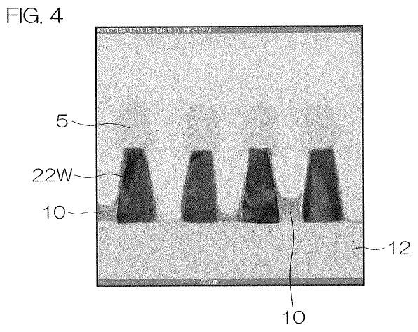

A microphotograph of a sample in a state where the dry etching (direct metal etching) of the molybdenum layer (metal wiring layer 22) is performed through the hard mask 5 that is made of silicon nitride (corresponding to FIG. 3A) is shown in FIG. 4. The residue is generated between the wirings 22W. In this example, a pitch between the adjacent wirings 22W is approximately 32 nm, and a height of the wirings 22W (thickness of the metal wiring layer 22) is approximately 64 nm. A transverse section of the wirings 22W is a trapezoidal shape, and a width of the wirings 22W is approximately 21 nm on a lower side of a trapezoidal cross-section and approximately 10 nm on an upper side.

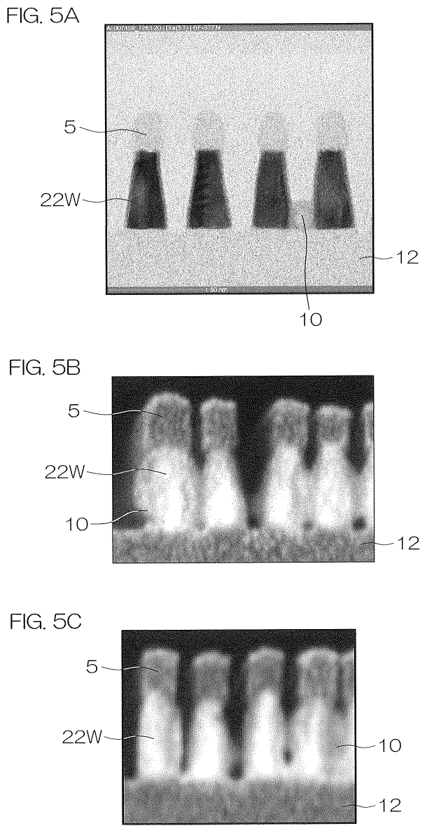

FIGS. 5A, 5B, and 5C show comparative examples in which, without performing the irradiation of the ultraviolet ray to the object surface to be processed of the sample, the processing liquid is supplied and the residue removal processing is performed.

FIG. 5A is a microphotograph in which the sample in a state of FIG. 4 was immersed in a hydrofluoric acid aqueous solution diluted by water to a concentration of 0.05 wt % of a room temperature for 2 minutes, then washed with water and dried, and after that photographed. It can be seen that the residue 10 remains between the wirings 22W, and the film reduction of the hard mask 5 is caused.

FIG. 5B is a microphotograph in which the sample in a state of FIG. 4 was immersed in the ammonium hydroxide for 2 minutes, then washed with water and dried, and after that photographed. As the ammonium hydroxide, diluted ammonium hydroxide made by diluting commercially available ammonium hydroxide (concentration of approximately 28 wt %) by 100 times by water was used at a room temperature. Also, FIG. 5C is a microphotograph in which the sample in a state of FIG. 4 was immersed in a TMAH aqueous solution for 2 minutes, then washed with water and dried, and after that photographed. The TMAH aqueous solution diluted by water to a concentration of 0.29 wt % to 5 wt % was used at a room temperature. In either of the cases shown in FIGS. 5B and 5C, the film reduction of the hard mask 5 was not observed but the residue 10 remains between the wirings 22W and the removal of the residue was incomplete.

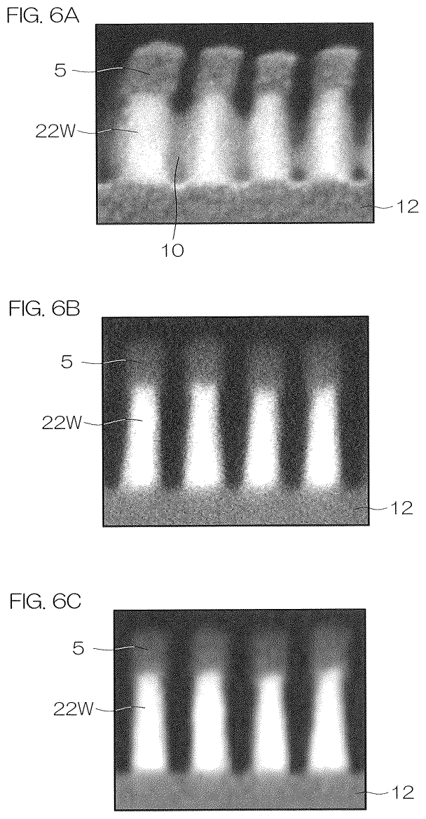

FIGS. 6A, 6B, and 6C show results of the irradiation of the ultraviolet ray performed on an object surface to be processed of the sample and then the residue removal processing performed by supplying the processing liquid. FIG. 6A is a comparative example, and FIGS. 6C and 6B are examples.

In any of the examples, the ultraviolet ray irradiation processing was executed by bringing and disposing the ultraviolet ray lamp unit close to the object surface to be processed of the sample by a distance of 2 mm in the sealed chamber. In addition, by supplying the inert gas (specifically, the nitrogen gas) into the sealed chamber, a portion between the ultraviolet ray lamp unit and the object surface to be processed is brought into an inert gas atmosphere (that is, the low oxygen atmosphere). An emission wavelength of the ultraviolet ray lamp was a range from 172 nm to 184 nm. A time of the irradiation of the ultraviolet ray was 30 seconds. Also, a temperature of the substrate 50 was a room temperature.

FIG. 6A (comparative example) is a microphotograph in which the ultraviolet ray irradiation processing described above was performed on the sample in a state of FIG. 4, then the sample was immersed in the hydrofluoric acid aqueous solution diluted by water to a concentration of 0.05 wt % of a room temperature for 2 minutes, then washed with water and dried, and after that photographed. It can be seen that the residue 10 remains between the wirings 22W, and the film reduction of the hard mask 5 is caused. In addition, it can be seen that the film reduction is also caused in the interlayer insulating film 12 (silicon oxide film) of the foundation.

FIG. 6B (example) is a microphotograph in which the ultraviolet ray irradiation processing described above was performed on the sample in a state of FIG. 4, then the sample was immersed in the ammonium hydroxide for 2 minutes, then washed with water and dried, and after that photographed. As the ammonium hydroxide, diluted ammonium hydroxide made by diluting commercially available ammonium hydroxide (concentration of approximately 28 wt %) by 100 times by water was used at a room temperature. Also, FIG. 6C (example) is a microphotograph in which the ultraviolet ray irradiation processing described above was performed on the sample in a state of FIG. 4, then the sample was immersed in the TMAH aqueous solution for 2 minutes, then washed with water and dried, and after that photographed. The TMAH aqueous solution diluted by water to a concentration of 0.29 wt % to 5 wt % was used at a room temperature. In either of the cases shown in FIGS. 6B and 6C, the film reduction of the hard mask 5 was not observed and the residue 10 between the wirings 22W was sufficiently removed.

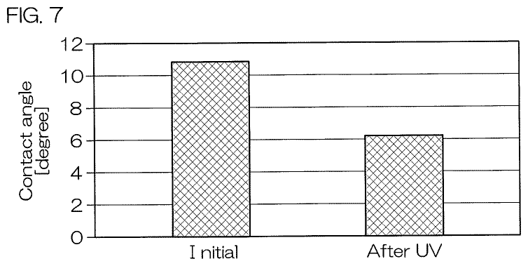

FIG. 7 is a view for describing another effect by the irradiation of the ultraviolet ray, showing an effect of an increase in a hydrophilic property by the irradiation of the ultraviolet ray. Specifically, FIG. 7 shows a result of examination of contact angles of water (deionized water) with respect to a surface of a molybdenum film, the left side shows a measurement result in an initial state (Initial), and the right side shows a measurement result after the irradiation of the ultraviolet ray (After UV). The contact angle in the initial state is 10.8 degrees, and the surface has a hydrophilic property even in the initial state. The contact angle after the irradiation of the ultraviolet ray is 6 degrees. It can be seen that the contact angle is reduced by the irradiation of the ultraviolet ray, and the hydrophilic property is increased.

By increasing the hydrophilic property, the residue removing liquid that is an aqueous solution easily soaks into the object surface to be processed of the substrate 50 (especially the surfaces of the wirings 22W). Thus, it is possible to make the residue removing liquid effectively act on the residue 10. That is, even when the metal wiring layer 22 has minute wiring patterns, it is possible to realize a particularly suitable liquid infiltration property into the minute patterns, and efficiently remove the residue 10 in the minute patterns.

Although the preferred embodiment of the present invention has been described above, the present invention can be implemented in further other preferred embodiments.

For example, in the preferred embodiment described above, the case where the main constituent metal of the metal layer is molybdenum is mainly described. However, the principle of the present invention can also be applied to a case where other metal materials are the main constituent metal of the metal layer. Specifically, the present invention can be applied to processing of a substrate that has a metal layer made of a metal material that can be patterned by the direct metal etching (dry etching). For example, in the semi-Damascene step, having resistivity acceptable as a wiring film, being capable of depositing without a diffusion barrier, and being capable of patterning by the dry etching (direct metal etching) are conditions at the time of selecting a wiring metal material. A metal that satisfies such conditions can be exemplified by molybdenum, ruthenium, and aluminum, as well as a molybdenum-based, a ruthenium-based, or an aluminum-based metal compound. It is also possible to apply the principle of the present invention to processing of a substrate that includes a metal layer made of these metal materials. Thereby, it is possible to reduce the risk of leakage between the wirings due to the residue, and it is also possible to reduce the risk of an increase in the specific resistance due to the film reduction of the wirings at the time of the residue removal processing.

Also, in the preferred embodiment described above, the semi-Damascene step is mainly described. However, it is possible to apply the present invention not only to the semi-Damascene step in which the via and the wiring film are formed at the same time, but also to a step that involves direct etching of the metal film. Specifically, the present invention may be applied to the residue removal processing after the direct etching (dry etching) of the wiring film in a wiring formation step of individually forming the via and the wiring film.

Also, the substrate to be processed (substrate of the foundation) is not limited to the semiconductor substrate but may be a substrate of other materials such as a glass substrate and a ceramic substrate.

Additionally, various design changes can be made within a range of the items described in the claims.

### REFERENCE SIGNS LIST

1: Silicon substrate
2: Multilayer wiring layer
5: Hard mask
6: Amorphous carbon layer
7: Photoresist mask
10: Residue
11: Interlayer insulating film
12: Interlayer insulating film
12a: Via opening
20: Metal wiring layer
21: Metal wiring layer
22: Metal wiring layer
22W: Wiring
22a: Via metal portion
23: Opening portion
31: Ultraviolet ray lamp unit
32: Inert gas nozzle
33: Sealed chamber
50: Substrate

1. A substrate processing method that processes a substrate having, on a surface thereof, a metal layer and a hard mask that is laminated on the metal layer, comprising:
dry etching and patterning the metal layer exposed from the hard mask;
irradiating an ultraviolet ray to a residue generated on the surface of the substrate by the dry etching, the residue containing one or more types of metal oxide, metallic halide, and an organic metallic substance each of which contains an element of a main constituent metal of the metal layer; and
removing the residue from the substrate by wet processing in which a residue removing liquid having a pH (hydrogen ion exponent) of not less than 7 and not more than 14 is supplied to the surface of the substrate after irradiation of the ultraviolet ray.

2. A substrate processing method for processing a substrate in which a hard mask and a metal layer patterned by dry etching through the hard mask are formed on a surface of the substrate, and in which a residue by the dry etching, the residue containing one or more types of metal oxide, metallic halide, and an organic metallic substance each of which contains an element of a main constituent metal of the metal layer is generated on the surface of the substrate, the substrate processing method comprising:
irradiating an ultraviolet ray to the residue; and
removing the residue from the substrate by wet processing in which a residue removing liquid having a pH (hydrogen ion exponent) of not less than 7 and not more than 14 is supplied to the surface of the substrate after irradiation of the ultraviolet ray.

3. The substrate processing method according to claim 1, wherein the metal layer contains, as the main constituent metal, at least one type selected from a metal material group consisting of molybdenum, ruthenium, and aluminum, and a metal compound containing these metals.

4. The substrate processing method according to claim 1, further comprising:
an atmosphere control to control an atmosphere in a periphery of the substrate during the irradiation of the ultraviolet ray to a low oxygen atmosphere of a lower oxygen concentration than an oxygen concentration in an air atmosphere.

5. The substrate processing method according to claim 4, wherein the atmosphere control-step includes an inert gas supply to supply an inert gas to the periphery of the substrate.

6. The substrate processing method according to claim 1, wherein the ultraviolet ray has energy that is not less than bond energy of at least one compound of the metal oxide, the metallic halide, and the organic metallic substance contained in the residue.

7. The substrate processing method according to claim 1, wherein the ultraviolet ray increases a hydrophilic property of a surface of the metal layer.

8. The substrate processing method according to claim 1, wherein the main constituent metal is molybdenum, and
a wavelength of the ultraviolet ray is not more than 257 nm.

9. The substrate processing method according to claim 1, wherein the residue removing liquid does not contain an oxidant but contains one or more selected from ammonium hydroxide, a tetramethylammonium hydroxide aqueous solution (TMAH), and a polymer removing liquid.

10. The substrate processing method according to claim 1, wherein the hard mask is made of an inorganic substance.

11. The substrate processing method according to claim 2, wherein the metal layer contains, as the main constituent metal, at least one type selected from a metal material group consisting of molybdenum, ruthenium, and aluminum, and a metal compound containing these metals.

12. The substrate processing method according to claim 2, further comprising:
an atmosphere control to control an atmosphere in a periphery of the substrate during the irradiation of the ultraviolet ray to a low oxygen atmosphere of a lower oxygen concentration than an oxygen concentration in an air atmosphere.

13. The substrate processing method according to claim 12, wherein the atmosphere control includes an inert gas supply to supply an inert gas to the periphery of the substrate.

14. The substrate processing method according to claim 2, wherein the ultraviolet ray has energy that is not less than bond energy of at least one compound of the metal oxide, the metallic halide, and the organic metallic substance contained in the residue.

15. The substrate processing method according to claim 2, wherein the ultraviolet ray increases a hydrophilic property of a surface of the metal layer.

16. The substrate processing method according to claim 2, wherein the main constituent metal is molybdenum, and
a wavelength of the ultraviolet ray is not more than 257 nm.

17. The substrate processing method according to claim 2, wherein the residue removing liquid does not contain an oxidant but contains one or more selected from ammonium hydroxide, a tetramethylammonium hydroxide aqueous solution (TMAH), and a polymer removing liquid.

18. The substrate processing method according to claim 2, wherein the hard mask is made of an inorganic substance.
